(19) United States
(12) Patent Application Publication
(10) Pub. No.: US 2011/0317356 A1
(43) Pub. Date: Dec. 29, 2011

(54) MEMORY SYSTEM, MEMORY MODULE, AND MODULE SOCKET

(75) Inventors: Takao ONO, Tokyo (JP); Atsushi MORISHIMA, Tokyo (JP)

(73) Assignee: ELPIDA MEMORY, INC., Tokyo (JP)

(21) Appl. No.: 13/165,305

(22) Filed: Jun. 21, 2011

(30) Foreign Application Priority Data
Jun. 23, 2010 (JP) 2010-142540

(51) Int. Cl. G06F 1/16; H05K 1/00

(52) U.S. Cl. 361/679.31; 361/748; 361/679.02

(57) ABSTRACT

The present invention is adapted to a memory system that includes: a motherboard and a module board, wherein: the motherboard comprises a module socket mounted on the motherboard; and a plurality of pins two-dimensionally arranged on the module socket, and vertically erected with respect to the motherboard: and the module board comprises a plurality of device chips installed on the module board; and a contact portion mounted on the module board, and including a plurality of through holes two-dimensionally arranged thereon, the contact portion being electrically connected to the device chips: wherein each of the pins is inserted into each of the through holes to connect electrically to the contact portion.

### BACKGROUND OF THE INVENTION

1. Field of the Invention

The present invention relates to a technique for installing memory modules each having a plurality of memories mounted thereon to a module socket.

2. Description of Related Art

Conventionally, it is often performed in a memory system using a large number of memories such as a DRAM (Dynamic Random Access Memory) that a plurality of memories are mounted on the module board of a memory module and the memory module is then installed in a module socket mounted on a motherboard. In addition, for the form of the module socket, a typical form is one in which a single memory module is vertically mounted on a motherboard as disclosed in JP2009-294864A and JP2010-027137A.

Now, in these years, in order to reduce the size and thickness of desktop personal computers, a trend has developed in which the motherboard is a small-sized motherboard such as MicroATX or Mini-ITX, and this trend is becoming the mainstream of memory systems as well.

However, in the form of typical modern module sockets, in the case that the number of memory modules to be installed is increased, the number of module sockets is increased correspondingly, so that the motherboard needs the area for module sockets. This goes against the trend toward a reduction in the size of the motherboard.

In addition, in the case of increasing the number of memory modules to be installed, the number of module sockets is increased correspondingly as discussed above. In this case, as regards the positions at which module sockets are placed, limitations are placed on the thickness of the module socket or on the wires or the like around the module socket. For this reason, a memory module installed in a module socket located at a position more apart from a CPU has a longer bus length to the CPU, and this bus length becomes a bottleneck against an increase in the speed of the memory system.

As described above, in the memory system, the problem to be solved is to install an increased number of memory modules without increasing the area of the motherboard. In addition, in the memory system, another problem to be solved is to install an increased number of memory modules without increasing the bus length between the CPU and the memory module.

### SUMMARY

In one embodiment, there is provided a memory system that includes: a motherboard and a module board, wherein: the motherboard comprises a module socket mounted on the motherboard; and a plurality of pins two-dimensionally arranged on the module socket, and vertically erected with respect to the motherboard: and the module board comprises a plurality of device chips installed on the module board; and a contact portion mounted on the module board, and including a plurality of through holes two-dimensionally arranged thereon, the contact portion being electrically connected to the device chips: wherein each of the pins is inserted into each of the through holes to connect electrically to the contact portion.

In another embodiment, there is provided a memory module that includes a module board; a plurality of device chips installed on the module board; and a contact portion mounted on the module board, and including a plurality of through holes two-dimensionally arranged thereon, the contact portion being electrically connected to the device chips.

In further another embodiment, there is provided a module socket that includes a motherboard; and a plurality of pins two-dimensionally arranged on the motherboard, and vertically erected with respect to the motherboard.

In accordance with the memory system according to the present invention, a plurality of pins, that are two-dimensionally arranged on the module socket, are vertically erected with respect to the motherboard, and a plurality of through holes are arranged on the module board, into which the plurality of pins are inserted.

Thus, it is possible to install the memory module to the module socket so that the memory module is horizontally installed with respect to the motherboard. In the case of increasing the number of memory modules to be installed, memory modules are stacked on a module socket for insertion.

Accordingly, because a single module socket is used to install a plurality of memory modules thereto, there is obtained the effect in which it is possible to increase the number of memory modules to be installed without increasing the area of a motherboard.

In addition, because a single module socket is used to install a plurality of memory modules thereto, no limitations are placed on the thickness of the module socket or the wires or the like around the module socket. Thus, the degree of freedom to arrange a module socket is increased, and it is also possible to mount a module socket at a position which is the shortest distance from a CPU. Accordingly, there is obtained the effect in which it is possible to increase the number of memory modules to be installed without increasing the bus length between a CPU and a memory module.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a perspective view depicting an exemplary configuration of a memory system according to an embodiment of the present invention;

FIG. 2 is a top view depicting an exemplary configuration of a memory module shown in FIG. 1;

FIG. 3 is a cross sectional view depicting an exemplary configuration of a module socket shown in FIG. 1;

FIG. 4 is a diagram illustrative of an exemplary method of contacting a pin shown in FIG. 1 with a through hole;

FIG. 5 is a diagram illustrative of an exemplary method of contacting a pin shown in FIG. 1 with a through hole;

FIG. 6 is a diagram illustrative of an exemplary method of contacting a pin shown in FIG. 1 with a through hole;

FIG. 7 is a diagram illustrative of an exemplary method of contacting a pin shown in FIG. 1 with a through hole;

FIG. 8 is a diagram illustrative of an exemplary method of applying a lateral pressure to a module board shown in FIG. 1;

FIG. 9 is a diagram illustrative of an exemplary relationship between the positions of the module socket shown in FIG. 1 and a CPU;

FIG. 10 is a diagram illustrative of an exemplary relationship between the positions of the module socket shown in FIG. 1 and a CPU;

FIG. 11A is a diagram illustrative of an exemplary effect of a typical memory system;

FIG. 11B is a diagram illustrative of an exemplary effect of the memory system shown in FIG. 1;

FIG. 11C is a diagram illustrative of an exemplary effect of the memory system shown in FIG. 1;

FIG. 12A is a diagram illustrative of an exemplary effect of the memory system shown in FIG. 1;

FIG. 12B is a diagram illustrative of an exemplary effect of the memory system shown in FIG. 1;

FIG. 13A is a diagram illustrative of an exemplary effect of the memory system shown in FIG. 1; and

FIG. 13B is a diagram illustrative of an exemplary effect of the memory system shown in FIG. 1.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### 1. Configuration of Memory System

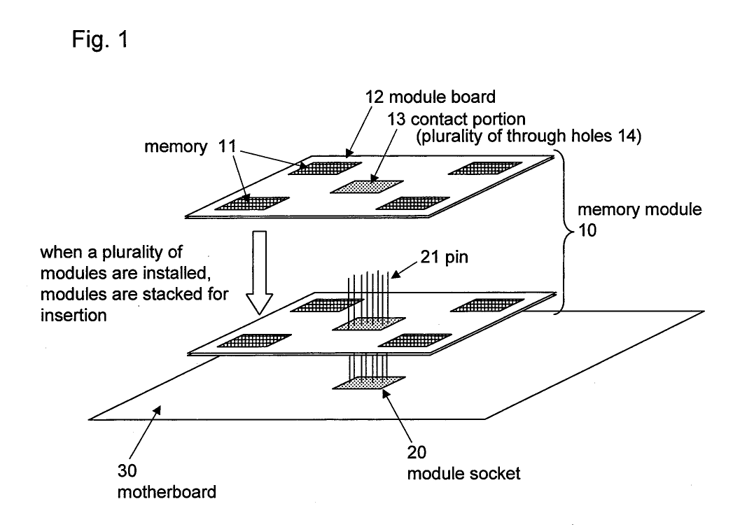

First, the configuration of a memory system according to this embodiment will be described with reference to FIG. 1. In addition, FIG. 1 extracts and shows only the configuration around memory module 10 and module socket 20.

As shown in FIG. 1, the memory system according to this embodiment includes memory module 10 having a plurality of memories 11, serving as a device chip, installed on module board 12, and module socket 20 mounted on motherboard 30 for installing memory module 10 thereto.

Here, module socket 20 is a pin socket having a plurality of pins 21 two-dimensionally arranged, and which is mounted in such a way that each of the plurality of pins 21 is vertically erected with respect to motherboard 30 and is connected electrically to a wire on motherboard 30. In addition, the term “vertical” includes those pins considered to be substantially vertical, not limited to being completely vertical.

In addition, memory module 10 includes contact portion 13 having a plurality of through holes 14 two-dimensionally arranged on module board 12 as corresponding to a plurality of pins 21, and corresponding pin 21 is inserted into each of the plurality of through holes 14 and is connected electrically to a wire on module board 12. Therefore, each of the plurality of pins 21 is connected electrically to contact portion 13, and contact portion 13 is connected electrically to contact memory 11. Thus, power or signals are supplied to memory 11 from pin 21 via through hole 14. In addition, because each through hole 14 is used for an electrode as discussed above, the inner wall is plated or coated with a conductive material, and has a diameter that is greater than the diameter of pin 21 so as to allow pin 21 to be inserted.

The memory system according to this embodiment is configured as described above, so that it is possible to install memory module 10 to module socket 20 horizontally with respect to motherboard 30. In addition, in the case where a plurality of memory modules 10 are installed to module socket 20, it is sufficient that memory modules 10 are stacked and that pins 21 of module socket 20 are inserted into through holes 14 in memory module 10.

In this embodiment, as described above with reference to FIG. 1, the effect in which it is possible to install a plurality of memory modules 10 horizontally to motherboard 30 will be described in detail below in 7-1.

### 2. Configuration of Memory Module 10

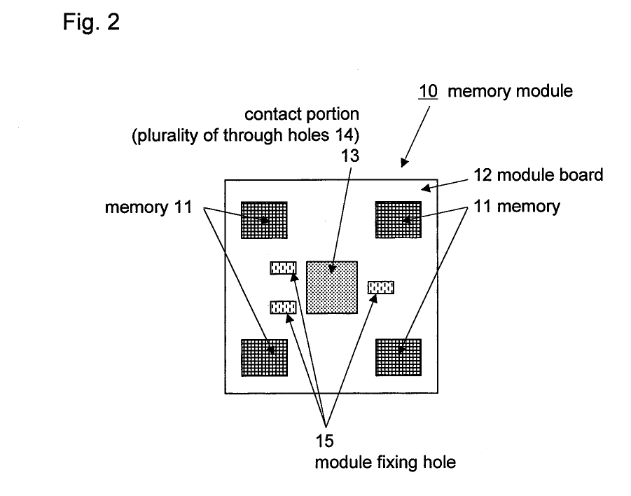

Next, the detailed configuration of memory module 10 will be described with reference to FIG. 2.

As shown in FIG. 2, on module board 12, contact portion 13 is arranged at almost the center part, and a plurality of memories 11 are installed around contact portion 13 so as to surround contact portion 13. In addition, module fixing hole 15 is arranged on module board 12 for fixing memory module 10 to module socket 20.

In this embodiment, as described with reference to FIG. 2 above, the effect in which it is possible to install a plurality of memories 11 around contact portion 13 at the center of module board 12 will be described in detail below in 7-2.

### 3. Configuration of Module Socket 20

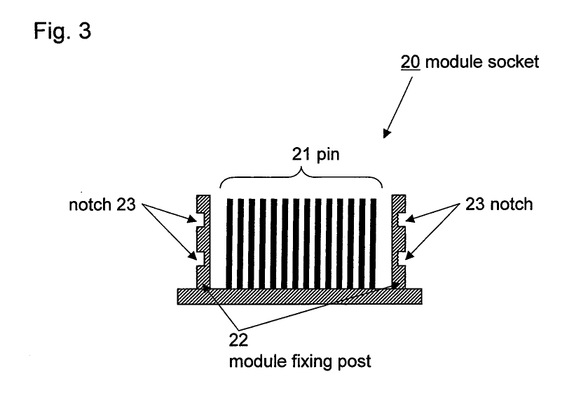

Next, the detailed configuration of module socket 20 will be described with reference to FIG. 3.

As shown in FIG. 3, in module socket 20, module fixing post 22 is provided, which has notch 23 for fixing memory module 10 to module socket 20, in addition to a plurality of pins 21.

In installing memory module 10 to module socket 20, pin 21 is inserted into through hole 14, and module fixing post 22 is inserted into module fixing hole 15. Module fixing hole 15 and notch 23 then engage with each other for fixing memory module 10 to module socket 20.

In addition, the length of pin 21 and the number of notches 23 provided in individual module fixing posts 22 are determined depending on the number of memory modules 10 to be installed to module socket 20. FIG. 3 shows the configuration in which installing two memory modules 10.

4. Method of Contacting Pin 21 with Through Hole 14

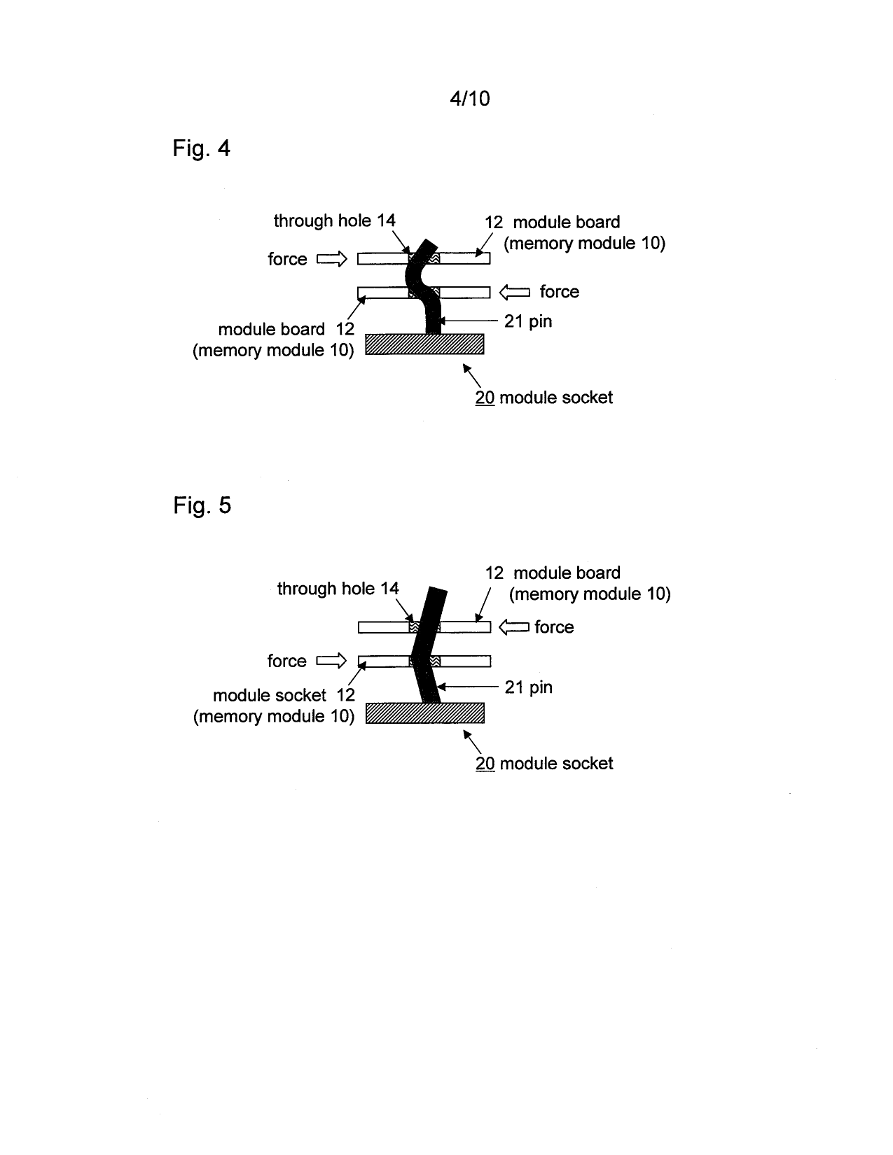

Next, a method of contacting pin 21 with the inner wall of through hole 14 will be described with reference to FIGS. 4 to 7.

In the example shown in FIG. 4, in installing memory module 10 to module socket 20, a lateral pressure applied to module board 12 causes pin 21 to bend in order to bring pin 21 into contact with the inner wall of through hole 14.

In the example shown in FIG. 5, pin 21 itself is bent in advance, and a lateral pressure applied to module board 12 causes pin 21 to come into contact with the inner wall of through hole 14 when installing memory module 10 to module socket 20.

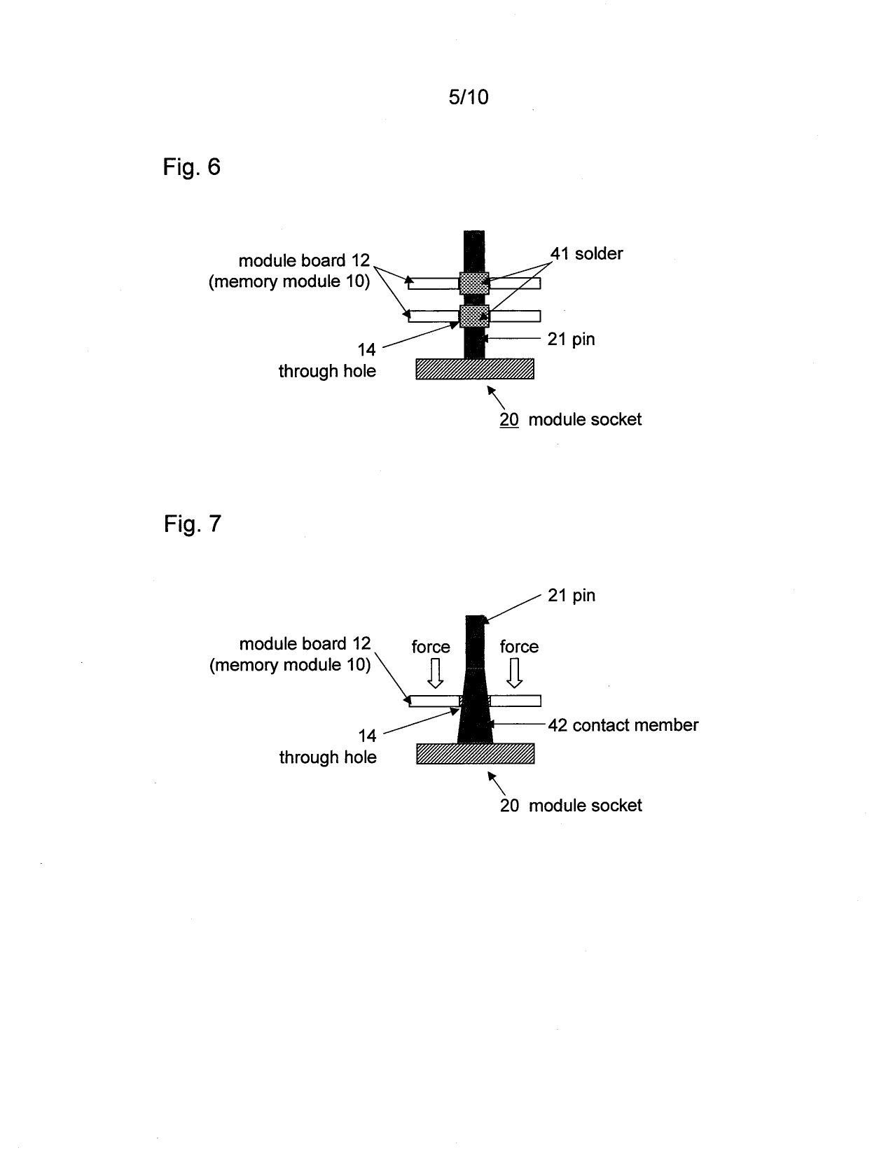

In the example shown in FIG. 6, pin 21 is soldered to through hole 14 with solder 41 so as to bring pin 21 into contact with the inner wall of through hole 14.

In the example shown in FIG. 7, metal contact member 42 in a triangular pyramid having a movable portion is attached to pin 21 so as to bring pin 21 into contact with the inner wall of through hole 14 via contact member 42 by a downward pressure applied to module board 12 when installing memory module 10 to module socket 20.

### 5. Method of Applying a Lateral Pressure on Module Board 12

Next, for the method of applying a lateral pressure to memory module 10 with reference to FIGS. 4 and 5, a method of applying a lateral pressure to individual module boards 12 in different directions will be described more specifically.

For a means for applying a lateral pressure to individual module boards 12 in different directions, consideration is given to such a configuration in which a spring or the like is used.

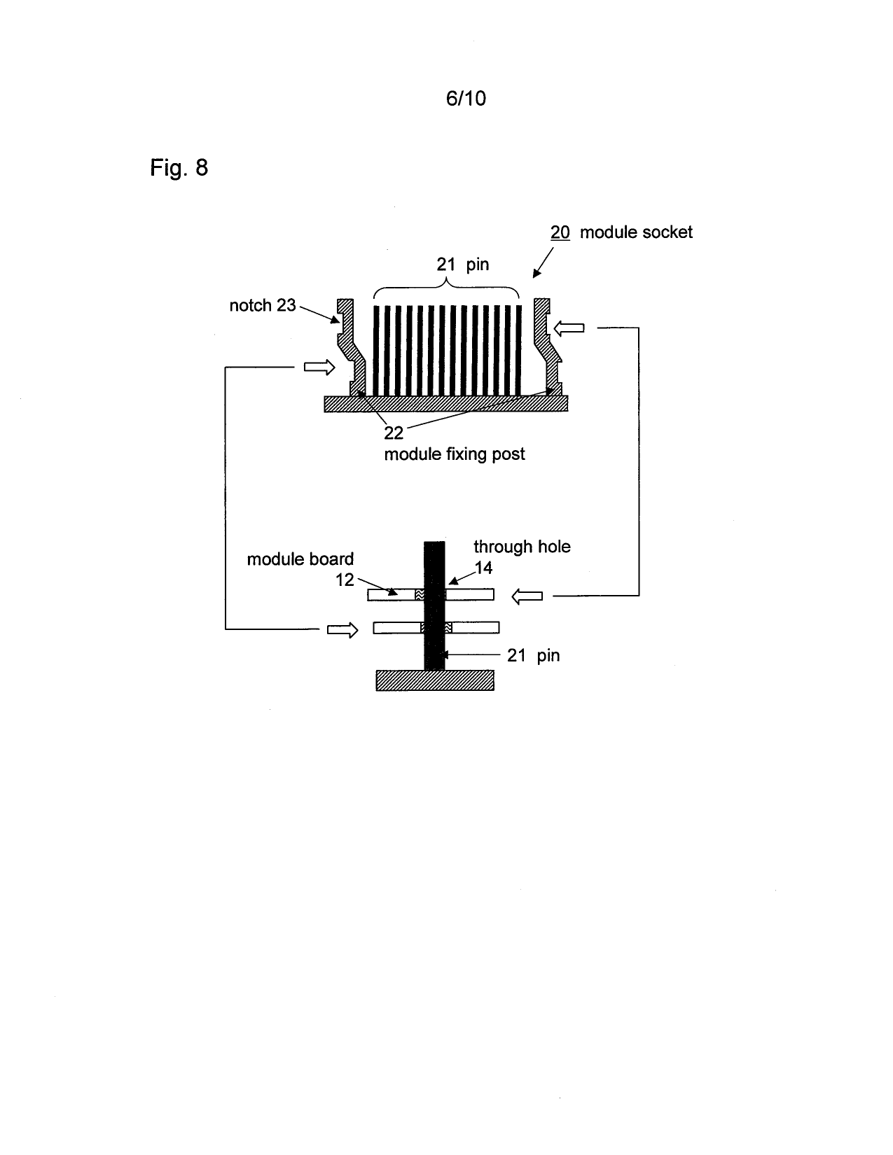

In contrast to this, as shown in FIG. 8, it is possible to implement the foregoing pressure applying means in which module fixing post 22 is bent in advance between the positions at which notches 23 are provided, and the positions of fixing memory modules 10 are shifted in individual module boards 12. With such a simple configuration, it is possible to apply pressure to individual module boards 12 in different directions.

6. Relationship between the Positions of Module Socket 20 and CPU 50

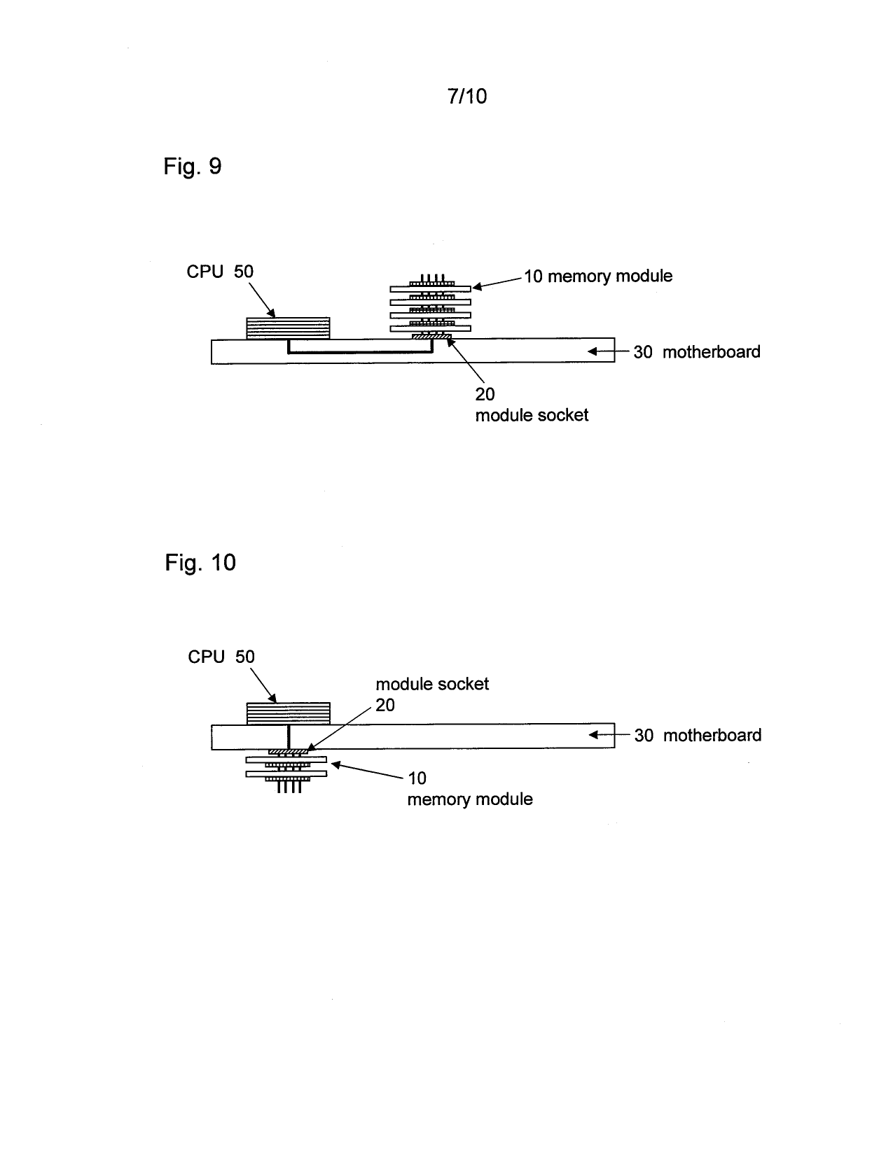

Next, the relationship between the positions of module socket 20 and CPU 50 will be described with reference to FIGS. 9 to 10.

In the example shown in FIG. 9, module socket 20 is mounted on the surface on which CPU 50 is also installed on motherboard 30.

In the example shown in FIG. 10, module socket 20 is mounted on the rear surface of motherboard 30 at the position opposite CPU 50 installed on the front surface of motherboard 30.

In this embodiment, the effect in which it is possible to arrange module socket 20 and CPU 50 in the position relationship as described with reference to FIGS. 9 and 10 will be described in detail below in 7-1.

### 7. Effects of the Memory System According to This Embodiment

### 7-1. First Effect

According to this embodiment, module socket 20 is a pin socket having a plurality of pins 21 two-dimensionally arranged, the pin socket is mounted in such a way that a plurality of pins 21 are vertically erected with respect to motherboard 30, and a plurality of through holes 14 are arranged on module board 12 of memory module 10, into which a plurality of pins 21 are individually inserted.

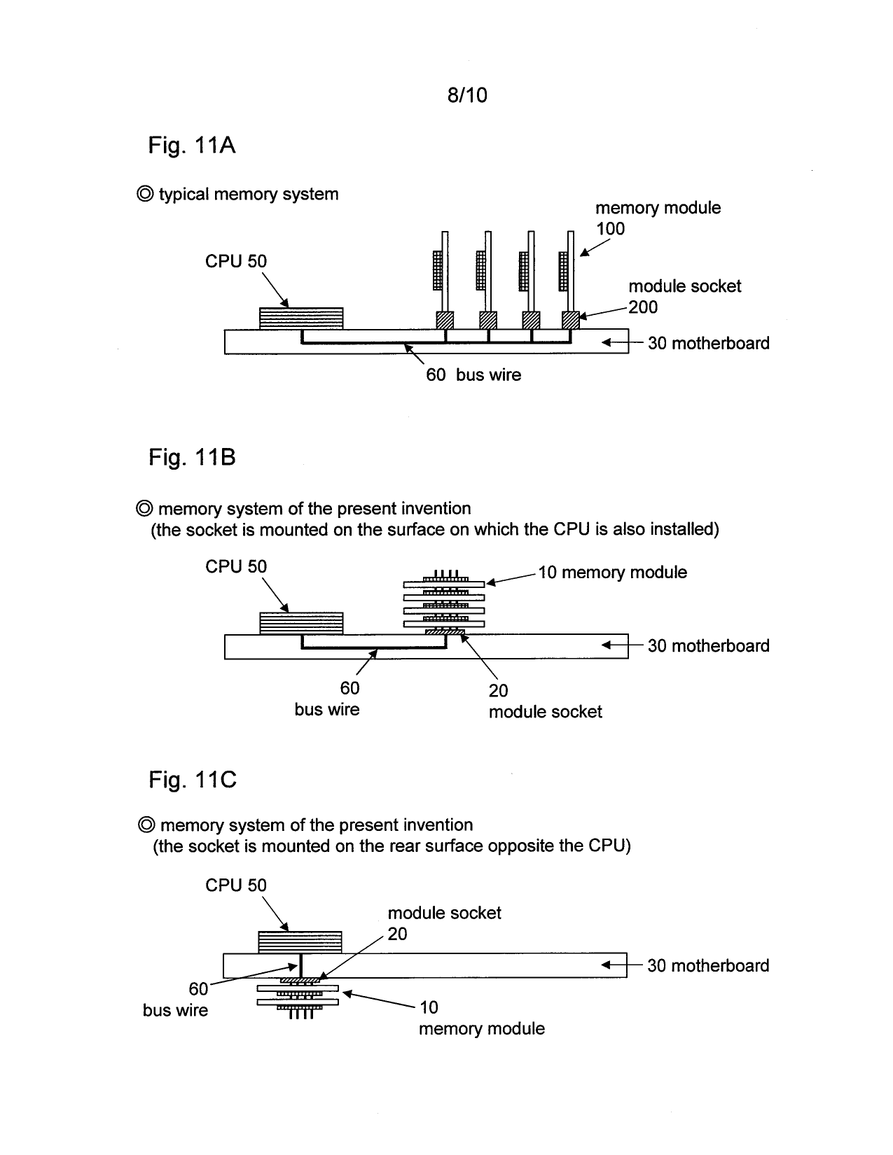

With this configuration, there is obtained a first effect in which it is possible to increase the number of memory modules 10 to be installed with no increase in the area of motherboard 30 and in the bus length between CPU 50 and memory module 10. The first effect will be described in detail below with reference to FIGS. 11A to 11C. In addition, FIG. 11A shows the typical configuration of a memory system studied by the inventor. FIG. 11B shows the configuration of the memory system according to the present invention shown in FIG. 9. FIG. 11C shows the configuration of the memory system according to the present invention shown in FIG. 10.

As shown in FIG. 11A, in the typical memory system, the form of module socket 200, into which memory module 100 is installed, is such that the module board is vertically installed on motherboard 30. Thus, in the case of increasing the number of memory module 100 to be installed, the number of module sockets 200 is increased correspondingly, resulting in an increase in the area of motherboard 30. Moreover, limitations are placed on the thickness of module socket 200 or on the wires or the like around module socket 200, so that it is difficult to arrange individual module sockets 200 to be close to each other, and the length of bus wire 60 (simply referred to as the bus length) between CPU 50 and memory module 100 depends on the position at which module socket 200 is placed.

In contrast to this, as shown in FIGS. 11B and 11C, in the memory system according to the present invention, it is possible to install memory modules 10 to module socket 20 as memory modules 10 are installed horizontally to motherboard 30. Furthermore, in the case of installing a plurality of memory modules 10 to module socket 20, memory modules 10 are stacked on each other, and pins 21 of module socket 20 are inserted into through holes 14 in memory module 10.

As a result, because it is possible to install a plurality of memory modules 10 to single module socket 20, it is possible to increase the number of memory modules 10 to be installed with no increase in the area of motherboard 30.

Moreover, because it is possible to install a plurality of memory modules 10 to single module socket 20, intervals between the positions of a plurality of memory modules 10 do not suffer from the limitations on the position at which module socket 20 is placed, and it is possible to install a plurality of memory modules 10 at the positions much closer to CPU 50. As a result, it is possible to increase the number of memory modules 10 to be installed with no increase in the bus length between CPU 50 and memory module 10.

Furthermore, as shown in FIG. 11C, in the case where module socket 20 is mounted on the rear surface of motherboard 30 at the position opposite CPU 50 installed on the front surface of motherboard 30, the bus length between CPU 50 and memory module 10 becomes the shortest.

### 7-2. Second Effect

In addition, according to this embodiment, a plurality of memories 11 are installed around contact portion 13 so as to surround contact portion 13 on memory module 10.

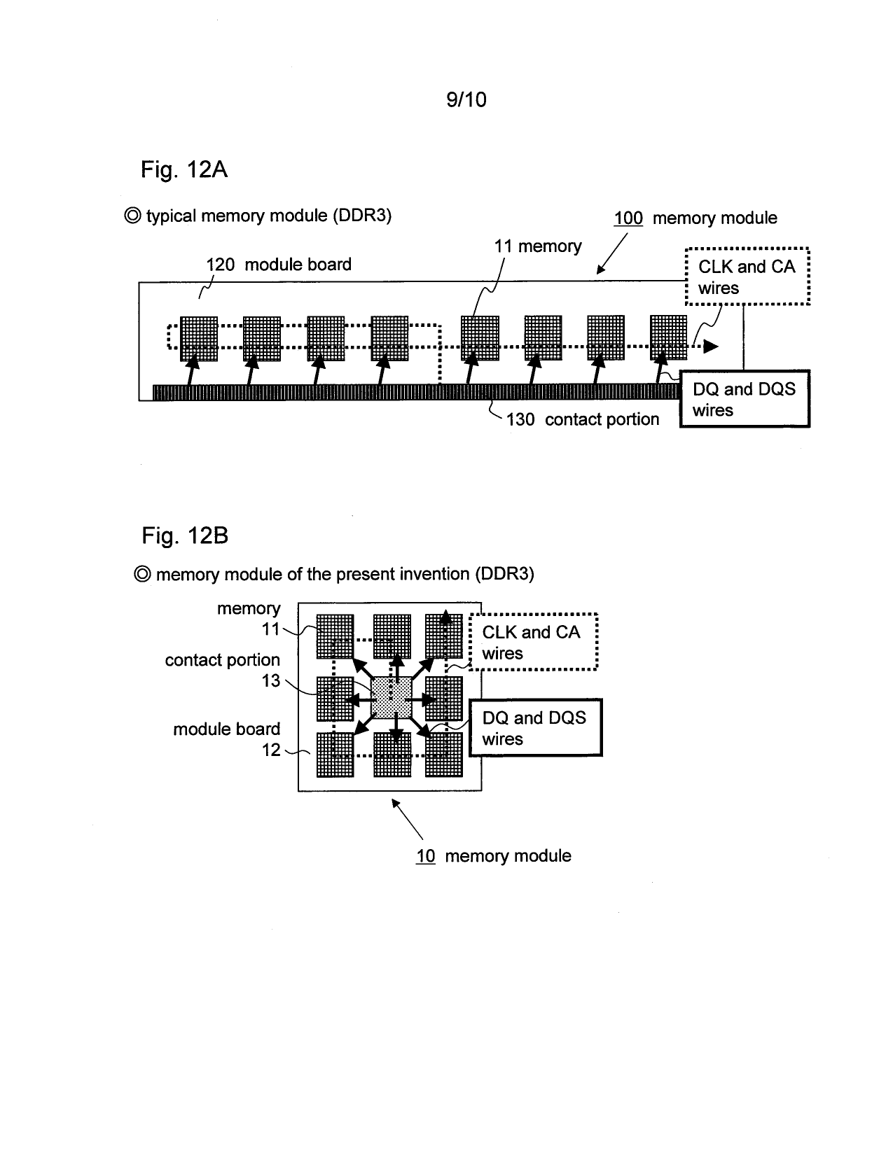

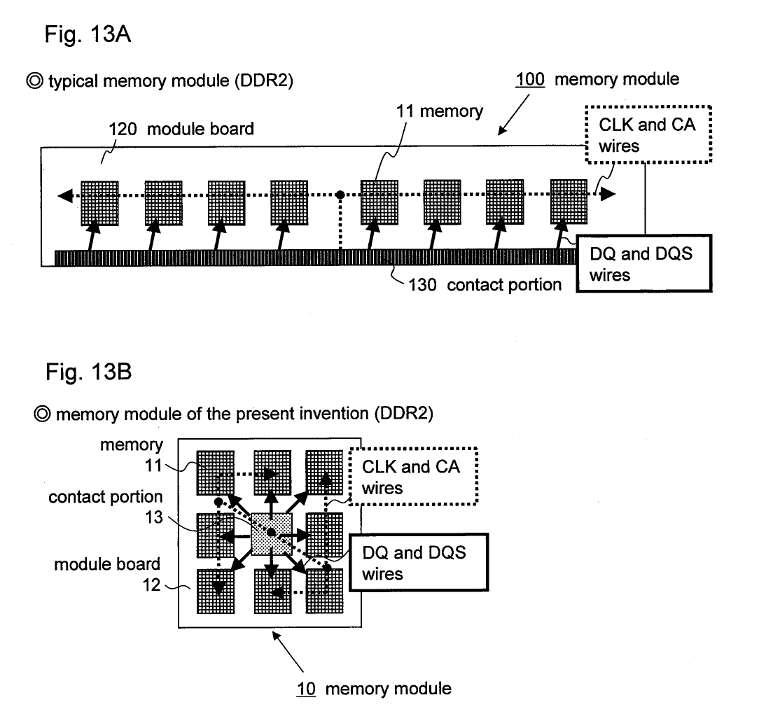

As a result, there is obtained a second effect in which it is possible to shorten the stub length between contact portion 13 and memory 11. The second effect will be described in detail below with reference to FIGS. 12A, 12B, 13A, and 13B. Moreover, FIG. 12A shows the configuration of typical memory module (DDR 3: Double Data Rate 3) 100 studied by the inventor, and FIG. 12B shows the configuration of memory module (DDR3) 10 according to the present invention. Furthermore, FIG. 13A shows the configuration of typical memory module (DDR 2: Double Data Rate 2) 100 studied by the inventor, and FIG. 13B shows the configuration of memory module (DDR2) 10 according to the present invention.

As shown in FIGS. 12A to 12B, in the case of the DDR3, branching the CLK (clock) wire and the CA (command address) wire is not allowed. Thus, as shown in FIG. 12A, in the typical DDR3, it is necessary to route a CLK wire and a CA wire from contact portion 130 to memory 11 located at one end of module board 120. In contrast to this, as shown in FIG. 12B, because this routing is unnecessary in the DDR3 according to the present invention, it is possible to shorten the stub length.

On the other hand, as shown in FIGS. 13A to 13B, in the case of the DDR2, branching the CLK wire and the CA wire is allowed. However, as shown in FIG. 13A, in the typical DDR2, because a CLK wire and a CA wire from contact portion 130 have to be branched at only one place, the stub lengths to memories 11 located at both ends of module board 120 are lengthened. In contrast to this, as shown in FIG. 13B, in the DDR2 according to the present invention, because a CLK wire and a CA wire can be branched at a plurality of places, it is possible to shorten the stub length by about a half.

In addition, because the stub length of the DQ (data) wire and the stub length of the DQS (DQ strobe) wire are the same in both cases of the DDR2 and DDR3, the description is omitted.

### 7-3. Other Effects

Moreover, according to this embodiment, because it is possible to install a plurality of memory modules 10 to single module socket 20, there is obtained the effect in which it is possible to reduce the bus wiring region on motherboard 30. Furthermore, because the dependency of the substrate length of module board 12 on the contact portion is eliminated (see contact portion 130 in FIGS. 12A and 13A), there is obtained the effect that the area of module board 12 is readily reduced.

In addition, according to this embodiment, module socket 20 is a pin socket having a plurality of pins 21 two-dimensionally arranged, and a plurality of through holes 13 are arranged on module board 12 of memory module 10, which individually correspond to a plurality of pins 21. Thus, in the case of increasing the number of pins, it is possible to two-dimensionally increase the numbers of pins 21 and through holes 13, and there is obtained the effect in which it is possible to control increases in the areas of motherboard 30 and module board 12.

It is apparent that the present invention is not limited to the above embodiments, but may be modified and changed without departing from the scope and spirit of the invention.

What is claimed is:

1. A memory system, comprising:
a motherboard comprising
a module socket mounted on the motherboard; and
a plurality of pins two-dimensionally arranged on the module socket, and vertically erected with respect to the motherboard; and
a module board comprising
a plurality of device chips installed on the module board; and
a contact portion mounted on the module board, and including a plurality of through holes two-dimensionally arranged thereon, the contact portion being electrically connected to the device chips,
wherein each of the pins is inserted into each of the through holes to connect electrically to the contact portion.

2. The memory system according to claim 1, further comprising:
a hole formed in the module board; and
a pole provided with a notch mounted on the module socket, the pole being inserted into the hole to engage with each other for fixing the module board.

3. The memory system according to claim 1, further comprising:
a CPU installed on the motherboard,
wherein the module socket is mounted on a surface of the motherboard on which the CPU is also installed.

4. The memory system according to claim 1, further comprising:
a CPU installed on the motherboard,
wherein the module socket is mounted on a rear surface of the motherboard at a position opposite the CPU installed on a front surface of said motherboard.

5. The memory system according to claim 1, wherein the plurality of device chips is arranged around the contact portion on the module board so that the plurality of device chips surrounds the contact portion.

6. The memory system according to claim 1, wherein the module board consists of a plurality of the module boards, and the plurality of module boards are installed as the plurality of module boards that are horizontally stacked with respect to the motherboard.

7. The memory system according to claim 1, wherein each of the plurality of device chips comprises dynamic random access memory.

8. A memory module, comprising:
a module board;
a plurality of device chips installed on the module board; and
a contact portion mounted on the module board, and including a plurality of through holes two-dimensionally arranged thereon, the contact portion being electrically connected to the device chips.

9. The memory module according to claim 8, further comprising:
a hole formed in the module board,
wherein the module board is fixed by inserting a pole provided with a notch into the hole to engage with each other.

10. The memory module according to claim 8, wherein the plurality of device chips is arranged around the contact portion on the module board so that the plurality of device chips surrounds the contact portion.

11. The memory system according to claim 8, wherein each of the plurality of device chips comprises dynamic random access memory.

12. A module socket, comprising:
a motherboard; and
a plurality of pins two-dimensionally arranged on the motherboard, and vertically erected with respect to the motherboard.

13. The module socket according to claim 12, further comprising:
a pole provided with a notch mounted on the motherboard, and being inserted into a hole of a board to engage with other for fixing the board.

14. The module socket according to claim 12, further comprising:
a CPU installed on the motherboard,
wherein the module socket is mounted on a surface of the motherboard on which the CPU is also installed.

15. The module socket according to claim 12, further comprising:
a CPU installed on the motherboard,
wherein the module socket is mounted on a rear surface of the motherboard at a position opposite the CPU installed on a front surface of said motherboard.
